(19) United States
(12) Patent Application Publication
(10) Pub. No.: US 2008/0197465 A1
(43) Pub. Date: Aug. 21, 2008

(54) SEMICONDUCTOR DEVICE AND METHOD OF MANUFACTURING THE SAME

(75) Inventor: Seiji Fujiwara, Kyoto (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 12/030,381

(22) Filed: Feb. 13, 2008

(30) Foreign Application Priority Data
Feb. 20, 2007 (JP) 2007-038713
Dec. 17, 2007 (JP) 2007-324126

(51) Int. Cl. H01L 23/495; H01L 21/52

(52) U.S. Cl. 257/676; 438/107; 257/E23.04; 257/E21.5

(57) ABSTRACT

Variations in fastening positions of semiconductor elements are eliminated by forming protrusions on a die pad so as to enclose the semiconductor elements before an adhesive that fastens the semiconductor elements to the die pad is wetted and spread.

### FIELD OF THE INVENTION

The present invention relates to a multi-element semiconductor device in which a plurality of semiconductor elements is arranged on a same plane, and a method of manufacturing the same.

### BACKGROUND OF THE INVENTION

Recently, in order to achieve cost reduction and downsizing in semiconductor devices, a multi-chip package has been proposed on which one of a plurality of semiconductor elements having functions that differ from each other and a plurality of semiconductor elements formed through processes that differ from each other is mounted on a same plane.

One conventional multi-chip package is structured such that a plurality of semiconductor elements is fastened on a die pad having a planar lead frame by a fastening adhesive, wherein the respective semiconductor elements are electrically connected to an inner lead portion of the lead frame and the semiconductor elements are electrically connected to each other by wire bonding.

However, in the conventional semiconductor device described above, when fastening the plurality of semiconductor elements on the die pad in a single operation, displacements of the semiconductor elements due to bleeding of the semiconductor elements together with the adhesive occur during fastening. Consequently, fastening positions of the semiconductor elements cannot be determined which, in turn, prevents intervals between the semiconductor elements from being determined. This results in a disadvantage in that the wire bonding on the semiconductor elements is difficult.

In addition, with the conventional semiconductor device described above, it is possible to prevent the semiconductor elements from bleeding with the adhesive in order to determine the intervals between the semiconductor elements by: selecting adhesives with different melting points; using the adhesive with a higher melting point first; and fastening the plurality of semiconductor elements in a plurality of operations. Unfortunately, in this case, a plurality of types of materials must be prepared and an increase in the number of man-hours occurs.

In consideration thereof, a semiconductor device is proposed wherein recesses whose sizes are greater than areas (outside dimensions) of semiconductor elements are provided on a die pad of a lead frame, and by spreading an adhesive in the recesses and disposing semiconductor elements on the same, it is possible to fix the semiconductor elements at predetermined positions, thereby eliminating variations in fastening positions of the semiconductor elements (for example, refer to Japanese Patent Laid-Open No. 58-31543). The conventional semiconductor device will now be described with reference to the drawings.

FIG. 9A is a schematic plan view showing the configuration of a die pad portion of the conventional semiconductor device, and FIG. 9B is a schematic cross section taken along profile C-C′ shown in FIG. 9A.

In FIGS. 9A and 9B, reference numeral 101 denotes a die pad, 102 denotes recesses, 103 denotes semiconductor elements and 104 denotes an adhesive.

As shown in FIGS. 9A and 9B, the recesses 102 whose sizes are slightly larger than areas of the semiconductor elements 103 are formed on the die pad 101. The semiconductor elements 103 are fixed within the recesses 102 by the adhesive 104.

Next, a method of manufacturing the conventional semiconductor device will be described with reference to FIG. 10.

First, in step S401, the adhesive 104 is poured into the recesses 102. In step S402, the semiconductor elements 103 are placed in the recesses 102 into which the adhesive 104 has been poured (die bonding), whereby the semiconductor elements 103 are fixed by means of the adhesive 104.

Subsequently, in step S403, electrode portions of the respective semiconductor elements 103 are electrically connected to an inner lead portion of the lead frame and the electrode portions of the respective semiconductor elements 103 are electrically connected to each other via thin metallic wires by wire bonding (wire bonding). After performing resin molding using an epoxy resin in step S404, in step S405, a tie bar and a lead are processed (dicing process). In step S406, a type, a trademark and the like are marked by a laser, and in step S407, testing of electrical properties and the like (final inspection) is performed.

A desired semiconductor device is completed by undergoing the processes described above (step S408).

As shown, by providing the recesses 102 whose sizes are slightly greater than the areas of the semiconductor elements 103 on the die pad 101, pouring the adhesive 104 in the recesses 102 and fixing the semiconductor elements 103 in the recesses 102, the adhesive 104 stays within the recesses 102 and the semiconductor elements 103 are fastened in the recesses 102. Thus, variations in the fastening positions of the semiconductor elements can be eliminated.

Consequently, it is possible to avoid situations due to variations in the fastening positions of the semiconductor elements 103 wherein the electrode portions of the respective semiconductor elements 103 cannot be electrically connected to the inner lead portion of the lead frame and the electrode portions of the respective semiconductor elements 103 cannot be electrically connected to each other by wire bonding.

### DISCLOSURE OF THE INVENTION

As described above, with the conventional semiconductor device, a lead frame having a die pad provided with recesses whose sizes are slightly greater than the areas (outside dimensions) of semiconductor elements to be mounted is prepared in advance. However, since the outside dimensions and shapes of the semiconductor elements differ among types, the conventional semiconductor device requires that lead frames be separately prepared.

In consideration of the conventional problems described above, an object of the present invention is to provide a semiconductor device that is capable of eliminating variations in the fastening positions of semiconductor elements without having to prepare a lead frame for each outside dimension or shape of the semiconductor element and a method of manufacturing the same.

In order to achieve the above-described object, a semiconductor device according to the present invention includes: a semiconductor element mounting portion; a plurality of semiconductor elements mounted on the semiconductor element mounting portion; protrusions formed at positions proximal to an outer peripheral side of the respective semiconductor elements so as to enclose each of the semiconductor elements; a fastening material, formed between each of the semiconductor elements and the semiconductor element mounting portion, which fastens each of the semiconductor elements to the semiconductor element mounting portion; an electrode portion provided at each of the semiconductor elements; and thin metallic wires to be connected to the electrode portion provided at each of the semiconductor elements. The protrusions are suitably formed by an insulator.

In addition, in the semiconductor device according to the present invention described above, the protrusions are formed around entire peripheries of the semiconductor elements. When forming the protrusions around the entire peripheries of the semiconductor elements in this manner, the protrusions are suitably formed at one of the same height as the fastening material, a height that is higher than the fastening material and lower than the semiconductor elements, and the same height as the semiconductor elements.

In addition, in the semiconductor device according to the present invention described above, the protrusions are formed so as to partially enclose the semiconductor elements. When the protrusions are formed so as to partially enclose the semiconductor elements in this manner, the protrusions are suitably disposed in areas other than an area below an area through which the thin metallic wires pass. In addition, the protrusions are suitably formed higher than the fastening material.

Furthermore, a semiconductor device according to the present invention includes: a semiconductor element mounting portion; a plurality of semiconductor elements mounted on the semiconductor element mounting portion; protrusions formed along lower parts of outer peripheral sides of the respective semiconductor elements around entire peripheries of the respective semiconductor elements; a fastening material, formed between each of the semiconductor elements and the semiconductor element mounting portion, which fastens each of the semiconductor elements to the semiconductor element mounting portion; an electrode portion provided at each of the semiconductor elements; and thin metallic wires to be connected to the electrode portions provided at each of the semiconductor elements. When forming the protrusions along the lower parts of the outer peripheral sides of the semiconductor elements in this manner, the protrusions are suitably formed at the same height as the fastening material. In addition, the protrusions are suitably formed by an insulator.

Moreover, a method of manufacturing a semiconductor device according to the present invention includes the steps of: disposing a fastening material in each of a plurality of semiconductor element disposition areas of a semiconductor element mounting portion; disposing a semiconductor element on each of the semiconductor element disposition areas in which the fastening material has been respectively disposed; forming protrusions on the semiconductor element mounting portion so as to enclose the respective semiconductor elements disposed on the respective semiconductor element disposition areas; wetting and spreading the respectively disposed fastening material, and fastening each of the semiconductor elements to the semiconductor element mounting portion by the respectively disposed fastening material.

Additionally, the method of manufacturing a semiconductor device according to the present invention includes the steps of: one of disposing a fastening material in each of a plurality of semiconductor element disposition areas of a semiconductor element mounting portion after either forming protrusions on respective outer peripheral sides of the plurality of semiconductor element disposition areas or forming protrusions so as to enclose the respective semiconductor element disposition areas, and either forming protrusions on outer peripheral sides of the respective semiconductor element disposition areas or forming protrusions so as to enclose the respective semiconductor element disposition areas after disposing a fastening material in the respective semiconductor element disposition areas; and fastening each of the semiconductor elements to the semiconductor element mounting portion by wetting and spreading the respectively disposed fastening material and subsequently disposing the semiconductor elements on the respective semiconductor element disposition areas.

According to the present invention, since protrusions are provided instead of recesses on a semiconductor element mounting portion, variations in fastening positions of semiconductor elements can be eliminated without having to prepare a lead frame for each outer dimension or shape of the semiconductor elements. Consequently, it is possible to avoid situations due to the variations in the fastening positions of the semiconductor elements wherein electrode portions of the respective semiconductor elements cannot be electrically connected to a lead terminal (inner lead portion) of the lead frame and the electrode portions of the respective semiconductor elements cannot be electrically connected to each other by wire bonding. As a result, a yield of electrical connections of semiconductor elements can be improved. In addition, since preparing only one type of a fastening material for die bonding shall suffice, the number of manufacturing man-hours for a semiconductor device can be suppressed and simplification of a semiconductor device manufacturing process can be achieved.

Furthermore, according to the present invention, as for a semiconductor device manufacturing process, merely adding a step for forming protrusions to a conventional semiconductor device manufacturing process (die bonding method) shall suffice. Moreover, since the sequence of the steps for forming protrusions can be changed, different die bonding methods can now be accommodated.

The present invention is useful in a multi-element resin molding semiconductor device in which a plurality of semiconductor elements is arranged on a same plane.

### BRIEF DESCRIPTION OF THE DRAWINGS

FIG. 1A is a schematic plan view showing a configuration example of a die pad portion of a resin molding semiconductor device according to an embodiment of the present invention, and FIG. 1B is a schematic cross section taken along profile A-A′ shown in FIG. 1A;

FIG. 2A is a schematic plan view showing another configuration example of the die pad portion of the resin molding semiconductor device according to the present embodiment, and FIG. 2B is a schematic side view of the same;

FIG. 2C is a schematic plan view showing another configuration example of the die pad portion of the resin molding semiconductor device according to the present embodiment;

FIG. 3A is a schematic plan view showing another configuration example of the die pad portion of the resin molding semiconductor device according to the present embodiment, and FIG. 3B is a schematic side view of the same;

FIG. 4A is a schematic plan view showing another configuration example of the die pad portion of the resin molding semiconductor device according to the present embodiment, and FIG. 4B is a schematic side view of the same;

FIG. 5A is a schematic plan view showing another configuration example of the die pad portion of the resin molding semiconductor device according to the present embodiment, and FIG. 5B is a schematic side view of the same;

FIG. 6A is a schematic plan view showing another configuration example of the die pad portion of the resin molding semiconductor device according to the present embodiment, and FIG. 6B is a schematic cross section taken along profile B-B′ shown in FIG. 6A;

FIG. 7 is a perspective view showing a configuration example of the resin molding semiconductor device according to the present embodiment;

FIGS. 8A, 8B and 8C are assembly flow diagrams showing three examples of method of manufacturing the resin molding semiconductor device according to the present embodiment;

FIG. 9A is a schematic plan view showing the configuration of a die pad portion of a conventional semiconductor device, and FIG. 9B is a schematic cross section taken along profile C-C′ shown in FIG. 9A; and

FIG. 10 is an assembly flow diagram showing a method of manufacturing the conventional semiconductor device.

### DESCRIPTION OF THE EMBODIMENT

A semiconductor device according to an embodiment of the present invention and a method of manufacturing the same will now be described with reference to the drawings.

Here, a description will be given on a multi-chip package (resin molding semiconductor device) achieving a multi-element arrangement by disposing a plurality of semiconductor elements on a same plane and performing resin molding on the same as a single package as an example.

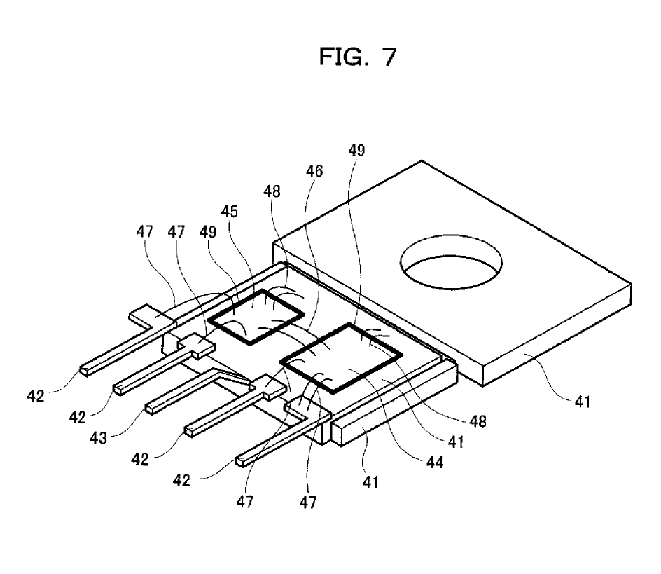

FIG. 7 is a perspective view showing a configuration example of a resin molding semiconductor device according to an embodiment of the present invention. In order to illustrate the configuration of the resin molding semiconductor device, the resin molding is not shown.

In FIG. 7: reference numeral 41 denotes a planar die pad (semiconductor element mounting portion) of a lead frame; 42 denotes lead terminals of the lead frame; 43 denotes a hanging lead that is a part of the lead terminals; 44 denotes a power semiconductor element that is required to supply current to the die pad 41; 45 denotes a control circuit semiconductor element that controls the power semiconductor element 44; 46 denotes first thin metallic wires that electrically connect a front face-side electrode portion of the power semiconductor element 44 to a front face-side electrode portion of the control circuit semiconductor element 45; 47 denotes second thin metallic wires that electrically connect the respective front face-side electrode portions of the power semiconductor element 44 and the control circuit semiconductor element 45 to the lead terminals 42; 48 denotes third thin metallic wires that electrically connect the respective front face-side electrode portions of the power semiconductor element 44 and the control circuit semiconductor element 45 to the die pad 41; and 49 denotes protrusions.

Note that electrode portions (front face-side electrode portion and rear face-side electrode portion) formed on the power semiconductor element 44 and the control circuit semiconductor element 45 are not shown in FIG. 7.

As shown in FIG. 7, the resin molding semiconductor device is provided with a plurality of the lead terminals 42 on the periphery of the die pad 41. The die pad 41 is connected to the hanging lead 43 that is a part of the lead terminals of the lead frame. The die pad 41 is positioned lower than the lead terminals 42 in order to ensure suitable resin flow in a transfer molding process and to reduce package thickness. The power semiconductor element 44 and the control circuit semiconductor element 45 are disposed in two predetermined areas (semiconductor element disposition areas) on the die pad 41. The die pad 41 has conducting and heat-radiating properties. The die pad 41 is electrically connected to the hanging lead 43.

A plurality of front face-side electrode portions are formed on surfaces of sides of the power semiconductor element 44 and the control circuit semiconductor element 45 opposite to the side of the die pad 41. The first thin metallic wires 46 electrically connect a part of the front face-side electrode portion of the power semiconductor element 44 to a part of the front face-side electrode portion of the control circuit semiconductor element 45. The second thin metallic wires 47 electrically connect parts of the respective front face-side electrode portions of the power semiconductor element 44 and the control circuit semiconductor element 45 to the lead terminals 42. The third thin metallic wires 48 electrically connect parts of the respective front face-side electrode portions of the power semiconductor element 44 and the control circuit semiconductor element 45 to the die pad 41. The power semiconductor element 44 and the control circuit semiconductor element 45 are disposed on the die pad 41 so as to maintain distances therebetween which enables connections by the thin metallic wires.

Since it is required that a current is supplied from the power semiconductor element 44 to the die pad 41, a conductive adhesive is used as an adhesive (fastening material), not shown, which fastens the power semiconductor element 44 and the control circuit semiconductor element 45 to the die pad 41. In order to obtain high reliability, a high-melting point eutectic solder of lead and tin is suitably used as the conductive adhesive. Using a conductive adhesive in this manner allows a rear face-side electrode portion formed on a rear face on the side of the die pad 41 of the power semiconductor element 44 to be electrically connected to the die pad 41 via the conductive adhesive, whereby a high current from the rear face-side electrode portion of the power semiconductor element 44 flows from a face of the die pad 41 on which the semiconductor elements are disposed to an opposite face of the die pad 41.

The protrusions 49 are formed on the die pad 41. The protrusions 49 respectively enclose the power semiconductor element 44 and the control circuit semiconductor element 45 disposed on the die pad 41 around the entire peripheries of the power semiconductor element 44 and the control circuit semiconductor element 45.

An adhesive that fastens the power semiconductor element 44 and the control circuit semiconductor element 45 to the die pad 41 is formed in each area enclosed by each protrusion 49.

By integrally molding the plurality of semiconductor elements with the lead frame using an epoxy resin or the like, the resin molding semiconductor device becomes a finished product that attains forms of various packages in which an outer lead protrudes from a mold.

Next, a connection state of the semiconductor elements to the die pad according to the present embodiment will be described.

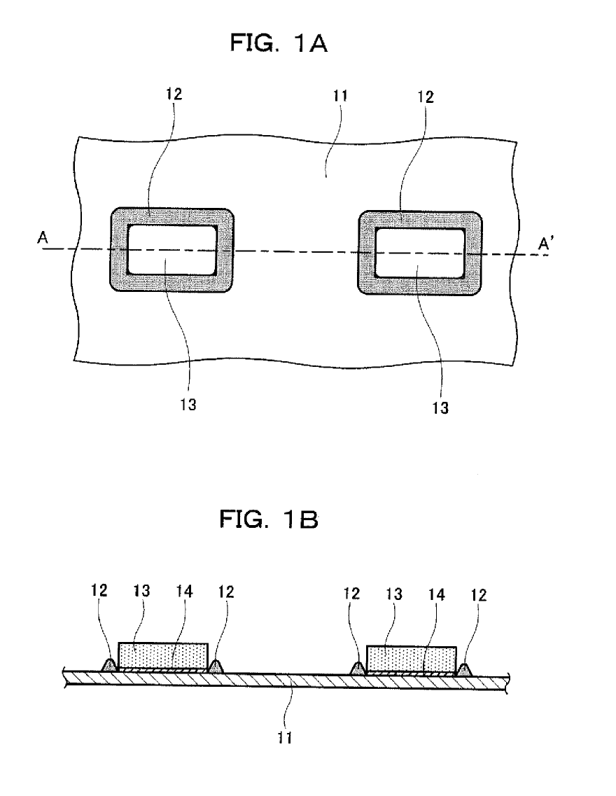

FIG. 1A is a schematic plan view showing a configuration example of a die pad portion of the resin molding semiconductor device according to the present embodiment of the present invention, and FIG. 1B is a schematic cross section taken along profile A-A′ shown in FIG. 1A.

In FIGS. 1A and 1B, reference numeral 11 denotes a die pad (semiconductor element mounting portion), 12 denotes protrusions, 13 denotes semiconductor elements and 14 denotes an adhesive (fastening material).

In this case, the die pad 11 corresponds to the die pad 41 shown in FIG. 7. The semiconductor elements 13 correspond to the power semiconductor element 44 and the control circuit semiconductor element 45 shown in FIG. 7. The protrusions 12 correspond to the protrusions 49 shown in FIG. 7.

As shown in FIGS. 1A and 1B, the protrusions 12 are formed at positions proximal to outer peripheral sides of the semiconductor elements 13 so as to enclose the semiconductor elements 13. The protrusions 12 are formed around entire peripheries of the semiconductor elements 13. The height of the protrusions 12 is set at one of the same height as the adhesive 14 formed in areas enclosed by the protrusions 12 (semiconductor element disposition areas), a height that is higher than the adhesive 14 and lower than the semiconductor elements 13, and the same height as the semiconductor elements 13. While a cross-sectional shape of the protrusions 12 is set so as to assume a shape that narrows down in a protruding direction or, in other words, an inverted-V shape, the cross-sectional shape of the protrusions 12 is not limited to this shape.

The adhesive 14 formed between the semiconductor elements 13 and the die pad 11 fastens the semiconductor elements 13 to the die pad 11.

In this manner, by forming the protrusions 12 that entirely enclose the semiconductor elements 13 at the positions proximal to the outer peripheral sides of the semiconductor elements 13, the semiconductor elements 13 can be fastened in predetermined areas (semiconductor element disposition areas) on the die pad 11.

In addition, by arranging the height of the protrusions 12 to be equal to or greater than the height of the adhesive 14, it is possible to prevent the adhesive 14 from spilling out of the outer peripheral sides of the semiconductor elements 13 or, in other words, the semiconductor element disposition areas when fastening the semiconductor elements 13 to the die pad 11.

As described earlier, a eutectic solder of lead and tin whose melting point is between 280 and 340° C. is used as the adhesive 14. A resin having a low linear expansion coefficient, a high Young's modulus (low elasticity) and which is an insulator is used for the protrusions 12. The resin used for the protrusions 12 is also a resin of a material that is resistant to deformation and the like even in a high-temperature state during wetting and spreading of the adhesive 14.

As described above, by setting the height of the protrusion 12 at a height that is lower than or the same as the semiconductor elements 13, wire bonding can be performed so that the thin metallic wires do not come into contact with the protrusions when electrically connecting the front face-side electrode portions of the respective semiconductor elements 13 to the lead terminal, the front face-side electrode portions of the respective semiconductor elements 13 to the die pad, and the front face-side electrode portions of the respective semiconductor elements 13 to each other with the thin metallic wires.

Next, another example of the protrusions according to the present embodiment will be described.

Although the protrusions 12 shown in FIG. 1 are formed around the entire peripheries of the semiconductor elements 13, the protrusions may be formed so as to partially enclose the semiconductor elements as described below.

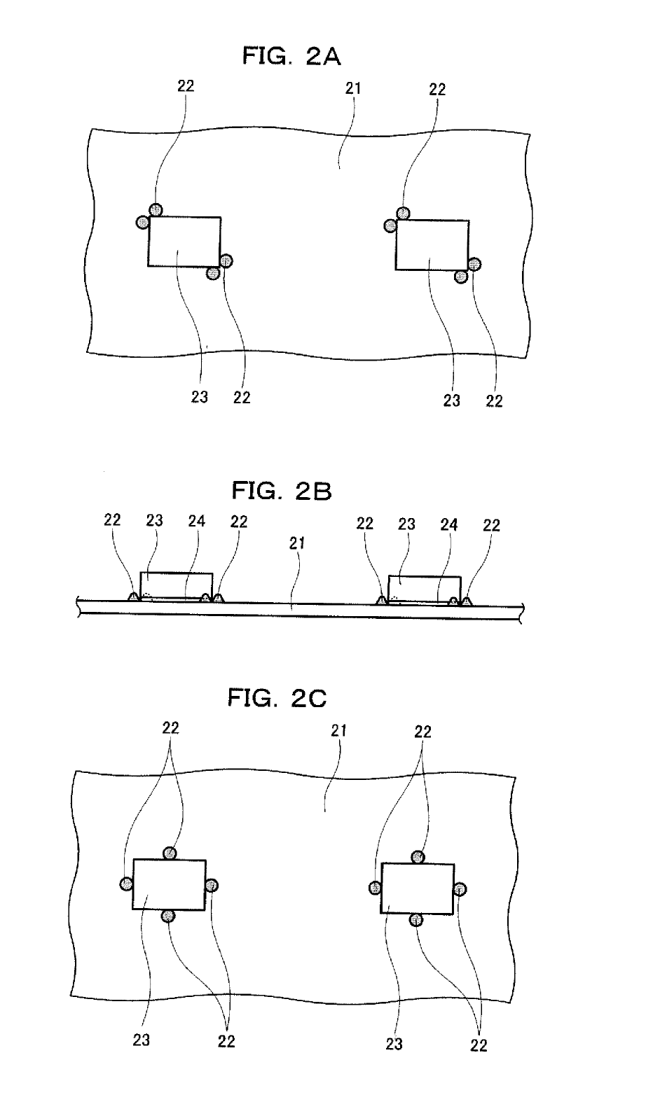

FIG. 2A is a schematic plan view showing a configuration example of the die pad portion of the resin molding semiconductor device according to the present embodiment of the present invention, and FIG. 2B is a schematic side view of the same.

In FIGS. 2A and 2E, reference numeral 21 denotes a die pad (semiconductor element mounting portion), 22 denotes protrusions, 23 denotes semiconductor elements and 24 denotes an adhesive (fastening material).

As shown in FIGS. 2A and 2B, the protrusions 22 are formed at positions proximal to outer peripheral sides of the semiconductor elements 23 so as to partially enclose the semiconductor elements 23. In this case, two protrusions 22 are respectively disposed in the proximity of two corners existing on a diagonal among four corners of the semiconductor elements 23 so as to embrace the two corners. The height of the protrusions 22 is set higher than the adhesive 24 formed on areas (semiconductor element disposition areas) enclosed by the protrusions 22. In this case, the shape of the protrusions 22 is set so as to assume a shape that narrows down in a protruding direction or, in other words, an approximately conic shape.

The adhesive 24 formed between the semiconductor elements 23 and the die pad 21 fastens the semiconductor elements 23 to the die pad 21.

In this manner, since partially enclosing the semiconductor elements 23 with the protrusions 22 that are higher than the adhesive 24 enables positions of the semiconductor elements 23 to be regulated by the protrusions 22 when fastening the semiconductor elements 23 to the die pad 21, the semiconductor elements 23 can be fastened so as not to spill out of the semiconductor element disposition areas.

While it is conceivable that the adhesive 24 will spill out of the semiconductor element disposition areas when the protrusions 22 are formed so as to partially enclose the semiconductor elements 23 in this manner, the semiconductor elements 23 whose positions are regulated by the protrusions 22 will not spill out of the semiconductor element disposition areas.

As described earlier, a eutectic solder of lead and tin whose melting point is between 280 and 340° C. is used as the adhesive 24. A resin having a low linear expansion coefficient, a high Young's modulus (low elasticity) and which is an insulator is used for the protrusions 22. The resin used for the protrusions 22 is a resin of a material that is resistant to deformation and the like even in a high-temperature state during wetting and spreading of the adhesive 24.

By forming the protrusions 22 as described above, a reduction in the material of the protrusions, a reduction in the formation time of the protrusions, and relaxation of stress due to an acyclicity of the protrusions can be anticipated. The protrusions 22 are disposed at areas other than an area below an area through which passes a thin metallic wire connected to front face-side electrode portions of the semiconductor elements 23 (for example, thin metallic wires that electrically connect the front face-side electrode portions of the respective semiconductor elements 23 to the inner lead portion of the lead terminal, thin metallic wires that electrically connect the front face-side electrode portions of the respective semiconductor elements 23 to each other, and thin metallic wires that electrically connect the front face-side electrode portions of the respective semiconductor elements 23 to the die pad 21). Since disposing the protrusions 22 in this manner removes restrictions on the shape of the thin metallic wires, a greater degree of freedom can be attained with respect to a layout of the respective front-side electrode portions of the semiconductor elements 23. At the same time, the quantity of the thin metallic wires can be minimized.

The arrangement of the protrusions 22 is not limited to the case where the protrusions 22 are disposed so as to embrace the corners, and the protrusions 22 may also be disposed in the proximity of a center of the respective sides of the semiconductor elements 23 as shown in FIG. 2C. The shape of the protrusions 22 is not limited to an approximately conic shape and may take any shape as long as the positions of the semiconductor elements 23 can be regulated.

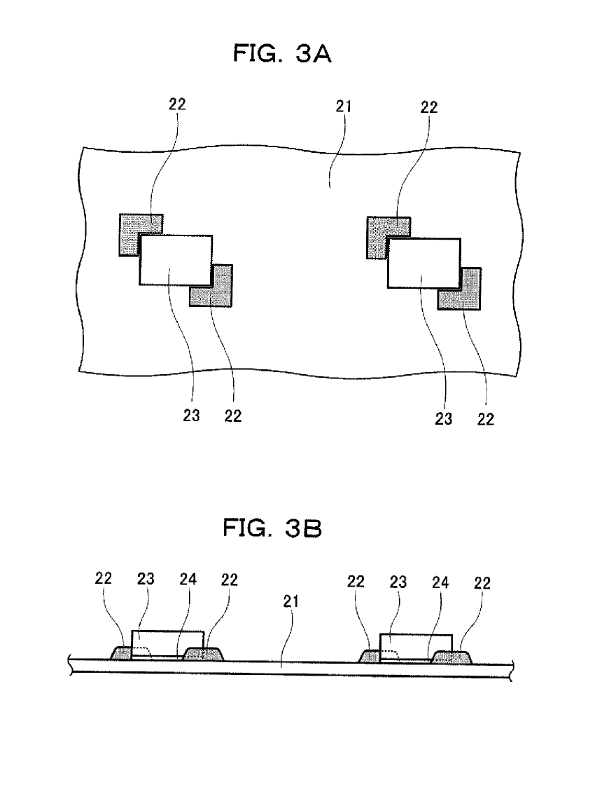

Next, three other examples of the protrusions 22 that partially enclose the semiconductor elements 23 are shown in FIGS. 3A, 3B to 5A, and 5B. FIGS. 3A to 5A are schematic plan views and FIGS. 3B to 5B are schematic side views of the same.

For example, as shown in FIGS. 3A and 3B, protrusions 22 whose sidewalls facing the semiconductor elements 23 have a plan view shape of an approximately L-shape may be respectively disposed in the proximity of two corners existing on a diagonal among the four corners of the semiconductor elements 23.

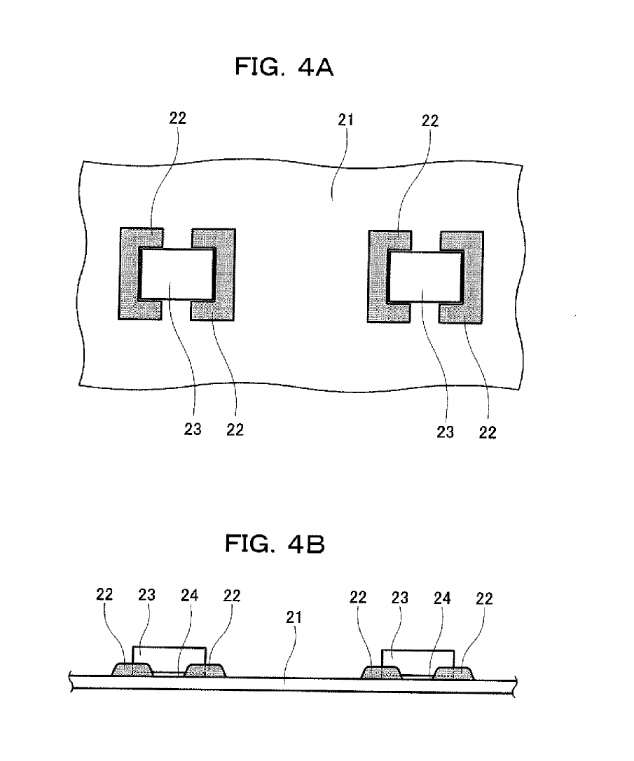

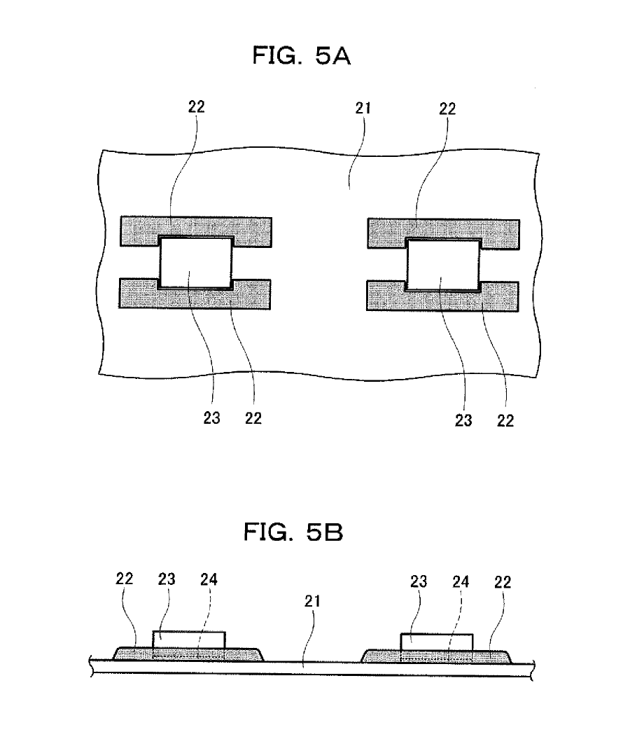

In addition, as shown in FIGS. 4A, 4B and 5A, 5B, protrusions 22 whose sidewalls facing the semiconductor elements 23 have a plan view shape of an approximately channel shape may be disposed so as to face each other.

While the protrusions are formed so as to enclose the semiconductor elements in the description given above, as will be described below, the protrusions may be formed along lower parts of outer peripheral sides of semiconductor elements disposed on the die pad.

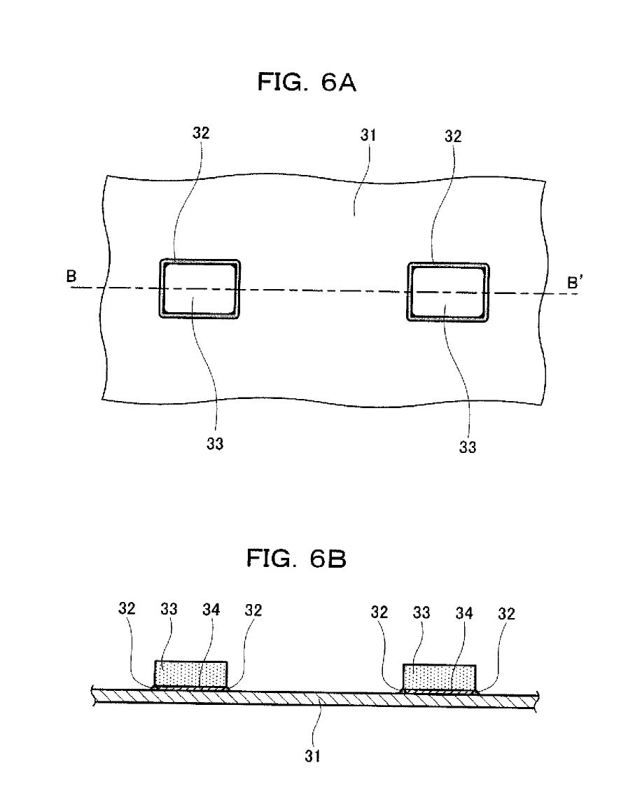

FIG. 6A is a schematic plan view showing a configuration example of the die pad portion of the resin molding semiconductor device according to the present embodiment of the present invention, and FIG. 6B is a schematic cross section taken along profile B-B′ shown in FIG. 6A.

In FIGS. 6A and 6B, reference numeral 31 denotes a die pad (semiconductor element mounting portion), 32 denotes protrusions, 33 denotes semiconductor elements and 34 denotes an adhesive (fastening material).

As shown in FIGS. 6A and 6B, the protrusions 32 are formed around entire peripheries of the semiconductor elements 33 along lower parts of outer peripheral sides of the semiconductor elements 33. While a cross-sectional shape of the protrusions 32 is set so as to assume a shape that narrows down in a protruding direction or, in other words, an inverted-V shape, the cross-sectional shape of the protrusions 32 is not limited to this shape.

The semiconductor elements 33 are fastened to the die pad 31 by the adhesive 34 formed between the semiconductor elements 33 and the die pad 31.

By forming the protrusions 32 in this manner, it is possible to prevent the adhesive 34 from spilling out of the outer peripheral sides of the semiconductor elements 33 or, in other words, predetermined areas on the die pad 31 (semiconductor element disposition areas) when fastening the semiconductor elements 33 to the die pad 31, and the semiconductor elements 33 can be fastened in the semiconductor element disposition areas.

As described earlier, a eutectic solder of lead and tin whose melting point is between 280 and 340° C. is used as the adhesive 34. A resin having a low linear expansion coefficient, a high Young's modulus (low elasticity) and which is an insulator is used for the protrusions 32. The resin used for the protrusions 32 is a resin of a material that is resistant to deformation and the like even in a high-temperature state during wetting and spreading of the adhesive 34.

The height of the protrusions 32 is set to one of the same height as the adhesive 34 and a lower height than the adhesive 34. More suitably, the height of the protrusions 32 is set to the same height as the adhesive 34 so that adhesion is entirely applied to areas that are necessary for radiating heat of the semiconductor elements 33.

A corner part of a semiconductor element fastened on a die pad whose thermal expansion coefficient significantly differs from that of the semiconductor element or an adhesive is a location where thermal stress concentrates due to structural reasons. As such, cracks, fissures and defects are likely to occur. According to the present embodiment, since the protrusions 32 made of a resin having a low linear expansion coefficient and a high Young's modulus are formed along the lower parts of the outer peripheral sides of the semiconductor elements 33, stress acting on corner parts of the semiconductor elements 33 can be alleviated and occurrences of cracks, fissures and defects on the semiconductor elements 33 can be suppressed.

By forming the protrusions 32 along the lower parts of the outer peripheral sides of the semiconductor elements 33, the protrusions 32 will no longer obstruct thin metallic wires connected to front face-side electrode portions of the semiconductor elements 33 (for example, thin metallic wires that electrically connect the front face-side electrode portions of the respective semiconductor elements 33 to the inner lead portion of the lead terminal, thin metallic wires that electrically connect the front face-side electrode portions of the respective semiconductor elements 33 to each other, and thin metallic wires that electrically connect the front face-side electrode portions of the respective semiconductor elements 33 to the die pad 31). As a result, the degree of freedom in layout will increase. At the same time, the quantity of the thin metallic wires can be minimized.

Next, a method of manufacturing the resin molding semiconductor device will be described below with reference to the drawings.

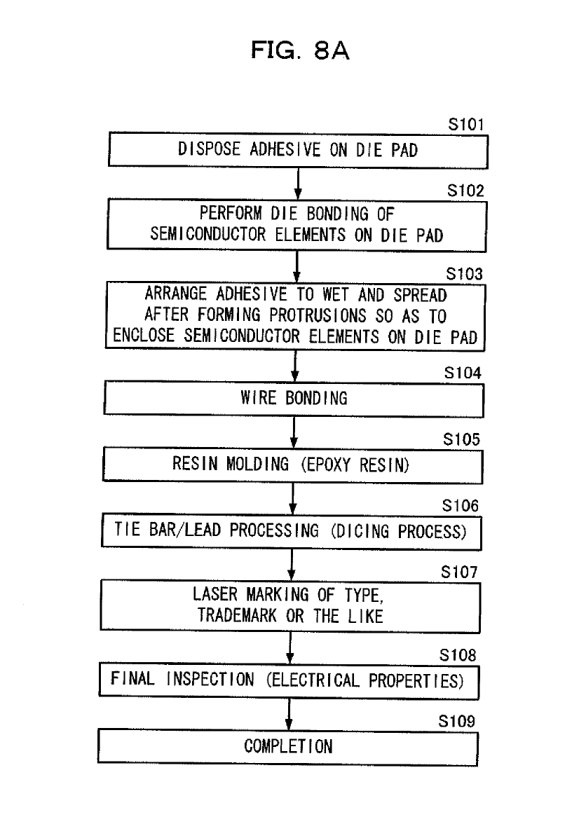

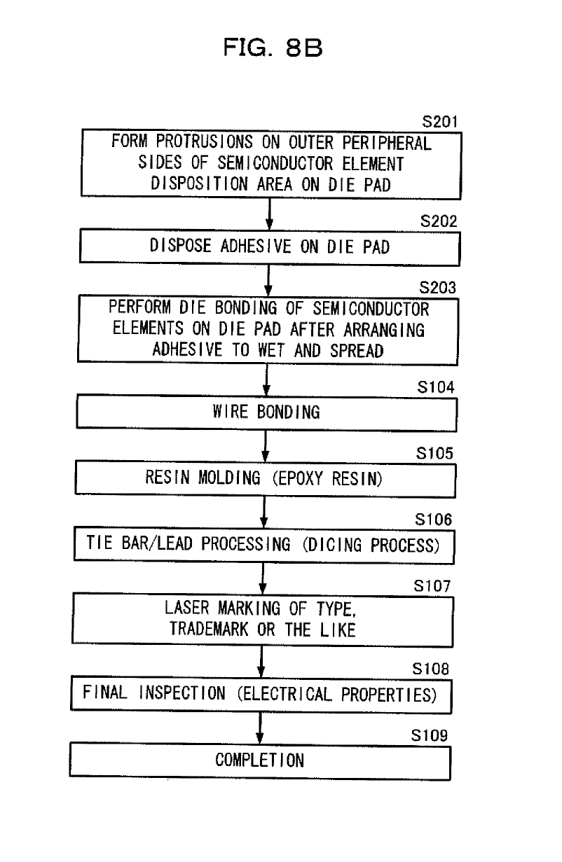

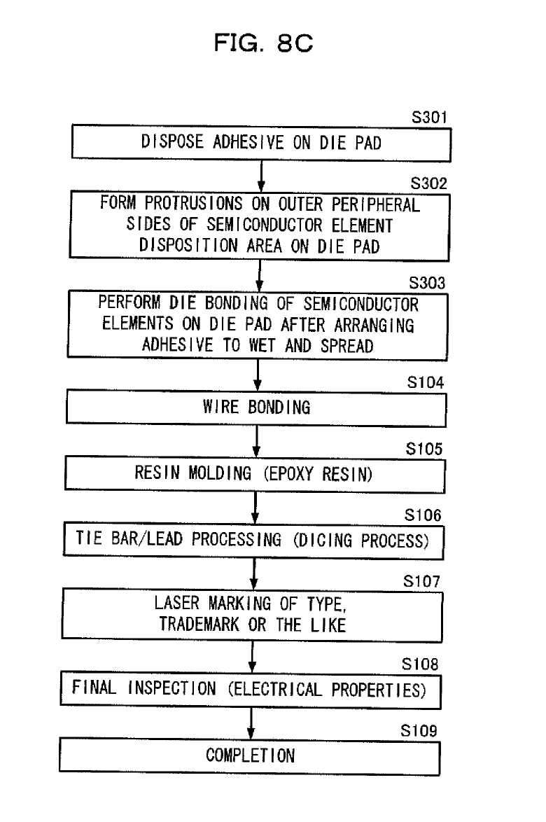

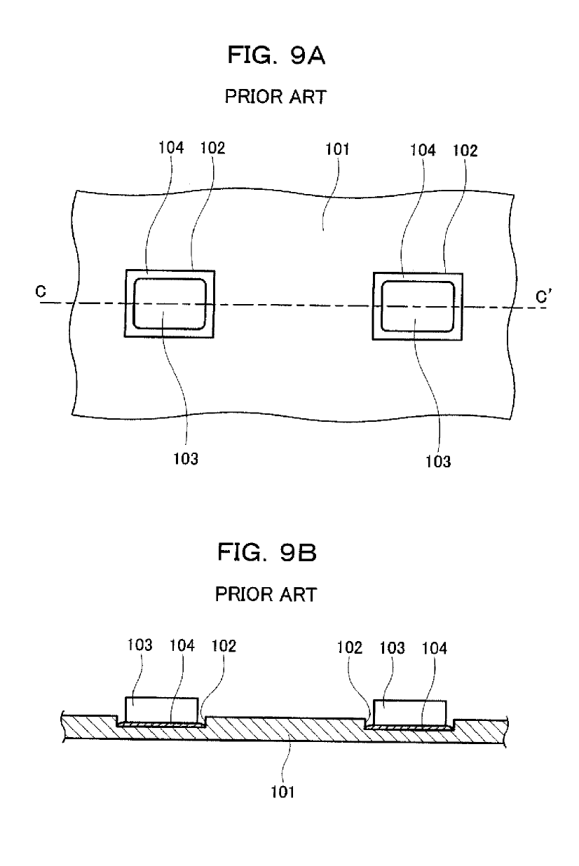

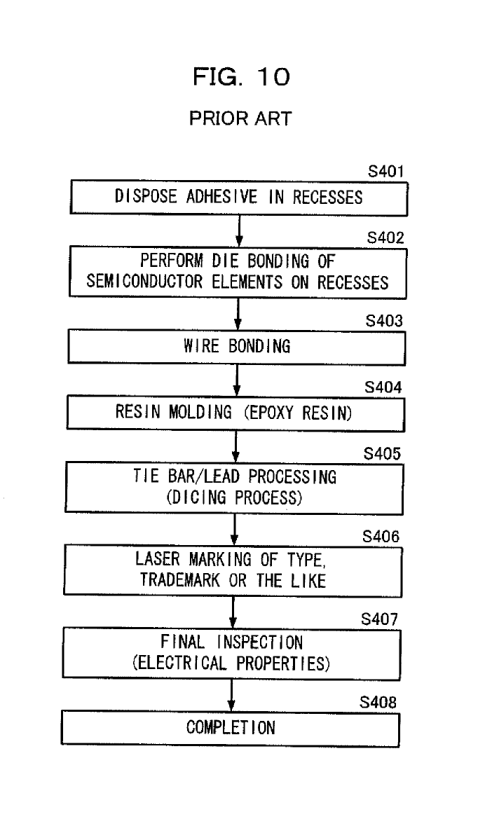

The method of manufacturing the resin molding semiconductor device where a connection state of the semiconductor elements to the die pad is the state shown in FIG. 1 will first be described with reference to FIG. 8A.

First, in step S101, the adhesive (fastening material) 14 is respectively disposed in a plurality of predetermined areas (semiconductor element disposition areas) on the die pad 11. Next, in step S102, the semiconductor elements 13 are disposed on the respective semiconductor element disposition areas in which the adhesive 14 is disposed (die bonding). Then, in step S103, after forming the protrusions 12 on the die pad 11 so as to respectively enclose the semiconductor elements 13 disposed on each of the semiconductor element disposition areas, the adhesive 14 is wetted and spread, whereby each semiconductor element 13 is fastened to the die pad 11 by the adhesive 14 that is respectively wetted and spread. In this case, the protrusions 12 are formed by applying resin in a low temperature-state equal to or lower than 280° C. so as to prevent solder that is the adhesive 14 from melting.

By forming the protrusions 12 that entirely enclose the semiconductor elements 13 before wetting and spreading the adhesive 14 in this manner, the adhesive 14 is stemmed by the protrusions 12. Therefore, the adhesive 14 is not excessively wetted and spread on the die pad 11.

Subsequently, in step S104, the front face-side electrode portions of the respective semiconductor elements 13 are electrically connected to the lead terminal of the lead frame, the front face-side electrode portions of the respective semiconductor elements 13 are electrically connected to the die pad 11, and the front face-side electrode portions of the respective semiconductor elements 13 are electrically connected to each other via thin metallic wires by wire bonding (wire bonding). After performing resin molding using an epoxy resin or the like in step S105, in step S106, a tie bar and a lead are processed (dicing process). In step S107, a type, a trademark and the like are marked on the resin molding by a laser, and in step S108, testing of electrical properties and the like (final inspection) is performed.

Through the process described above, a desired resin molding semiconductor device (finished product) that attains forms of various packages in which an outer lead protrudes from a resin mold is completed (step S109).

In this case, a loop height of the thin metallic wires when performing wire bonding is set to a height where the thin metallic wires do not come into contact with entire peripheral edge portions of the semiconductor elements 23 or the protrusions 22 and also where the loops are not exposed from the resin molding.

The above-described method of manufacturing a resin molding semiconductor device can be used to manufacture a resin molding semiconductor device wherein protrusions are formed on a die pad so as to partially enclose semiconductor elements as shown in FIGS. 2A, 2B and the like. More specifically, in the above-described manufacturing method, the step in which protrusions that entirely enclose semiconductor elements are formed only needs to be replaced with a step in which protrusions that partially enclose semiconductor elements (semiconductor element disposition areas) are formed.

Next, a first example of a method of manufacturing a resin molding semiconductor device where a connection state of the semiconductor elements to the die pad is the state shown in FIG. 6 will be described with reference to FIG. 8B.

First, in step S201, protrusions 32 are respectively formed around entire peripheries of a plurality of predetermined areas (semiconductor element disposition areas) on outer peripheral sides of the semiconductor element disposition areas on the die pad 31. The protrusions 32 are formed by applying a resin. In step S202, an adhesive (fastening material) 34 is disposed in each of the areas enclosed by the protrusions 32. Next, in step S203, after respectively wetting and spreading the adhesive 34, the semiconductor elements 33 are respectively disposed on the areas enclosed by the protrusions 32 (die bonding), whereby each of the semiconductor elements 33 is fastened to the die pad 31 by the respectively wetted and spread adhesive 34. Since the subsequent steps are the same as steps S104 to S109 described earlier, a description thereof will be omitted.

In this case, while the adhesive 34 is wetted and spread in step S203 after disposing the adhesive 34 in step S202, since the adhesive 34 is disposed after forming the protrusions 32, for example, when a wire-shaped solder or a ribbon-shaped solder is supplied as the adhesive 34, melting may be performed by a heater while supplying the solder in step S202.

Next, a second example of a method of manufacturing the resin molding semiconductor device where a connection state of the semiconductor elements to the die pad is the state shown in FIG. 6 will be described with reference to FIG. 8C.

First, in step S301, the adhesive (fastening material) 34 is respectively disposed in a plurality of predetermined areas (semiconductor element disposition areas) on the die pad 31. In step S302, the protrusions 32 are formed around entire peripheries of the semiconductor element disposition areas on respective outer peripheral sides of the semiconductor element disposition areas. The protrusions 32 are formed by applying resin in a low temperature-state equal to or lower than 280° C. so as to prevent solder that is the adhesive from melting. Next, in step S303, after respectively wetting and spreading the adhesive 34, the semiconductor elements 33 are disposed on each of the areas enclosed by the protrusions 32 (die bonding), whereby the respective semiconductor elements 33 are fastened to the die pad 31 by the respectively wetted and spread adhesive 34. Since the subsequent steps are the same as steps S104 to S109 described earlier, a description thereof will be omitted.

By forming the protrusions 32 around entire peripheries of the semiconductor element disposition areas on the respective outer peripheral sides of the semiconductor element disposition areas before wetting and spreading the adhesive 14 in this manner, the adhesive 34 is stemmed by the protrusions 32. Therefore, the adhesive 34 is not excessively wetted and spread on the die pad 31. Consequently, it is possible to avoid situations due to variations in the fastening positions of the semiconductor elements wherein front face-side electrode portions of the respective semiconductor elements cannot be electrically connected to an inner lead portion of the lead terminal, front face-side electrode portions of the respective semiconductor elements cannot be electrically connected to the die pad, and the front face-side electrode portions of the respective semiconductor elements cannot be electrically connected to each other by wire bonding.

A resin molding semiconductor device in which a connection state of the semiconductor elements to the die pad is the state shown in FIG. 1 can be manufactured using the first and second examples of the method of manufacturing a resin molding semiconductor device in which a connection state of the semiconductor elements to the die pad is the state shown in FIG. 6. More specifically, in the first and second examples described above, the step in which protrusions are formed on outer peripheral sides of the semiconductor element disposition areas only needs to be replaced by a step in which protrusions are formed so as to entirely enclose the semiconductor element disposition areas.

In a similar manner, a resin molding semiconductor device in which protrusions that partially enclose semiconductor elements are formed on a die pad as shown in FIGS. 2A, 2B and the like can be manufactured using the first and second examples of the method of manufacturing a resin molding semiconductor device in which a connection state of the semiconductor elements to the die pad is the state shown in FIG. 6. More specifically, in the first and second examples described above, the step in which protrusions are formed on outer peripheral sides of the semiconductor element disposition areas only needs to be replaced by a step in which protrusions that partially enclose the semiconductor element disposition areas are formed.

While a description of a case where two semiconductor elements are mounted has been given for the present embodiment described above, the present invention may also be applied to a case where, for example, at least three semiconductor elements are mounted. In addition, while a case where a die pad of a lead frame is used as a semiconductor element mounting portion has been described, a metallic flat plate that functions as a heat radiating plate may be used instead.

What is claimed is:

1. A semiconductor device comprising:
a semiconductor element mounting portion;
a plurality of semiconductor elements mounted on the semiconductor element mounting portion;
protrusions formed at positions proximal to an outer peripheral side of each of the semiconductor elements so as to enclose each of the semiconductor elements;
a fastening material, formed between each of the semiconductor elements and the semiconductor element mounting portion, which fastens each of the semiconductor elements to the semiconductor element mounting portion;
an electrode portion provided at each of the semiconductor elements; and
thin metallic wires to be connected to the electrode portion provided at each of the semiconductor elements.

2. The semiconductor device according to claim 1, wherein the protrusions are formed around entire peripheries of the respective semiconductor elements.

3. The semiconductor device according to claim 2, wherein the protrusions are formed at one of the same height as the fastening material formed between each of the semiconductor elements enclosed by the protrusions and the semiconductor element mounting portion, a height that is higher than the fastening material formed between each of the semiconductor elements and the semiconductor element mounting portion and lower than each of the semiconductor elements, and the same height as each of the semiconductor elements.

4. The semiconductor device according to claim 1, wherein the protrusions are formed so as to partially enclose the respective semiconductor elements.

5. The semiconductor device according to claim 4, wherein the protrusions are disposed at areas other than an area under an area through which the thin metallic wires pass.

6. The semiconductor device according to claim 4, wherein the protrusions are formed higher than the fastening material.

7. The semiconductor device according to claim 1, wherein the protrusions are formed by an insulator.

8. A semiconductor device comprising:
a semiconductor element mounting portion;
a plurality of semiconductor elements mounted on the semiconductor element mounting portion;
protrusions formed along lower parts of outer peripheral sides of the respective semiconductor elements around entire peripheries of the respective semiconductor elements;
a fastening material, formed between each of the semiconductor elements and the semiconductor element mounting portion, which fastens each of the semiconductor elements to the semiconductor element mounting portion;
an electrode portion provided at each of the semiconductor elements; and
thin metallic wires to be connected to the electrode portion provided at each of the semiconductor elements.

9. The semiconductor device according to claim 8, wherein the protrusions are formed so as to have the same height as the fastening material formed between each of the semiconductor elements enclosed by the protrusions and the semiconductor element mounting portion.

10. The semiconductor device according to claim 8, wherein the protrusions are formed by an insulator.

11. A method of manufacturing a semiconductor device comprising the steps of:
disposing a fastening material in each of a plurality of semiconductor element disposition areas of a semiconductor element mounting portion;
disposing a semiconductor element on each of the semiconductor element disposition areas in which the fastening material has been respectively disposed;
forming protrusions on the semiconductor element mounting portion so as to enclose the respective semiconductor elements disposed on the respective semiconductor element disposition areas; and
wetting and spreading the respectively disposed fastening material, and fastening each of the semiconductor elements to the semiconductor element mounting portion by the respectively disposed fastening material.

12. A method of manufacturing a semiconductor device comprising the steps of:
one of disposing a fastening material in each of a plurality of semiconductor element disposition areas of a semiconductor element mounting portion after either forming protrusions on respective outer peripheral sides of the plurality of semiconductor element disposition areas or forming protrusions so as to enclose the respective semiconductor element disposition areas, and either forming protrusions on respective outer peripheral sides of the respective semiconductor element disposition areas or forming protrusions so as to enclose the respective semiconductor element disposition areas after disposing a fastening material in the respective semiconductor element disposition areas; and
fastening each of semiconductor elements to the semiconductor element mounting portion by wetting and spreading the respectively disposed fastening material and subsequently disposing the respective semiconductor elements on the respective semiconductor element disposition areas.
